(19) United States
(12) Patent Application Publication
(10) Pub. No.: US 2024/0421020 A1
(43) Pub. Date: Dec. 19, 2024

(54) SEMICONDUCTOR PACKAGE

(71) Applicant: SAMSUNG ELECTRONICS CO., LTD., Suwon-si (KR)

(72) Inventor: YOUNG KWAN SEO, Suwon-si (KR)

(21) Appl. No.: 18/389,699

(22) Filed: Dec. 19, 2023

(30) Foreign Application Priority Data
Jun. 14, 2023 (KR) 10-2023-0076190

(51) Int. Cl. H01L 23/31; H01L 21/56; H01L 23/00; H01L 25/065

(52) U.S. Cl. CPC H01L 23/3178; H01L 21/565; H01L 23/3185; H01L 24/08; H01L 24/80; H01L 25/0652; H01L 25/0657; H01L 24/16; H01L 2224/08145; H01L 2224/16225; H01L 2224/80895; H01L 2224/80896; H01L 2225/06527; H01L 2225/06541; H01L 2924/10158; H10B 80/00

(57) ABSTRACT

A semiconductor package may include a base semiconductor chip, a connection semiconductor chip on the base semiconductor chip, an upper semiconductor chip on the connection semiconductor chip, a filling layer in a trench in the upper semiconductor chip, and a mold layer extending around the upper semiconductor chip.

### CROSS-REFERENCE TO RELATED APPLICATIONS

This U.S. non-provisional patent application claims priority under 35 U.S.C. § 119 to Korean Patent Application No. 10-2023-0076190, filed on Jun. 14, 2023, in the Korean Intellectual Property Office, the disclosure of which is hereby incorporated by reference in its entirety.

### BACKGROUND OF THE INVENTION

The present disclosure relates to semiconductor packages, and in particular, to semiconductor packages including a filling layer.

A semiconductor package is configured to easily use an integrated-circuit chip as a part of an electronic product. In general, a semiconductor package includes a printed circuit board (PCB) and a semiconductor chip, which is mounted on the PCB and is electrically connected to the PCB using bonding wires or bumps. With development of the semiconductor industry, many studies are being conducted to improve reliability of semiconductor packages.

### SUMMARY

An embodiment of the inventive concept provides a semiconductor package with improved electrical and reliability characteristics.

According to an embodiment of the inventive concept, a semiconductor package may include a base semiconductor chip, a connection semiconductor chip on the base semiconductor chip, an upper semiconductor chip on the connection semiconductor chip, wherein the upper semiconductor ship includes a trench, a filling layer in the trench, and a mold layer extending around the upper semiconductor chip.

According to an embodiment of the inventive concept, a semiconductor package may include a base semiconductor chip, a connection semiconductor chip on the base semiconductor chip, an upper semiconductor chip on the connection semiconductor chip, a filling layer in the upper semiconductor chip, and a mold layer extending around the upper semiconductor chip. The upper semiconductor chip may include an inner side surface in contact with the filling layer and an outer side surface in contact with the mold layer.

According to an embodiment of the inventive concept, a semiconductor package may include a base semiconductor chip, terminals connected to the base semiconductor chip, a connection semiconductor chip on the base semiconductor chip, an upper semiconductor chip on the connection semiconductor chip, a filling layer in the upper semiconductor chip, and a mold layer extending around the connection semiconductor chip and the upper semiconductor chip. The upper semiconductor chip may include a lower pad in contact with the connection semiconductor chip, an interconnection structure electrically connected to the lower pad, and an upper substrate on the interconnection structure. The upper substrate may include a lower portion and a plurality of upper portions, and the plurality of upper portions of the upper substrate may be spaced apart from each other by the filling layer.

According to an embodiment of the inventive concept, a method of fabricating a semiconductor package may include forming a base semiconductor chip, forming a connection semiconductor chip on the base semiconductor chip, forming a trench in an upper semiconductor chip, and bonding the upper semiconductor chip to the connection semiconductor chip.

### BRIEF DESCRIPTION OF THE DRAWINGS

FIG. 1A is a sectional view illustrating a semiconductor package according to an embodiment of the inventive concept.

FIG. 1B is a plan view illustrating the semiconductor package of FIG. 1A.

FIGS. 2A, 2B, 2C, 2D, 2E, 2F, and 2G are sectional views illustrating a method of fabricating the semiconductor package of FIGS. 1A and 1B.

FIG. 3 is a plan view illustrating a semiconductor package according to an embodiment of the inventive concept.

FIG. 4 is a plan view illustrating a semiconductor package according to an embodiment of the inventive concept.

FIG. 5 is a plan view illustrating a semiconductor package according to an embodiment of the inventive concept.

FIG. 6 is a plan view illustrating a semiconductor package according to an embodiment of the inventive concept.

FIG. 7 is a plan view illustrating a semiconductor package according to an embodiment of the inventive concept.

FIG. 8 is a plan view illustrating a semiconductor package according to an embodiment of the inventive concept.

FIG. 9 is a sectional view illustrating a semiconductor package according to an embodiment of the inventive concept.

### DETAILED DESCRIPTION

Example embodiments of the inventive concepts will now be described more fully with reference to the accompanying drawings, in which example embodiments are shown.

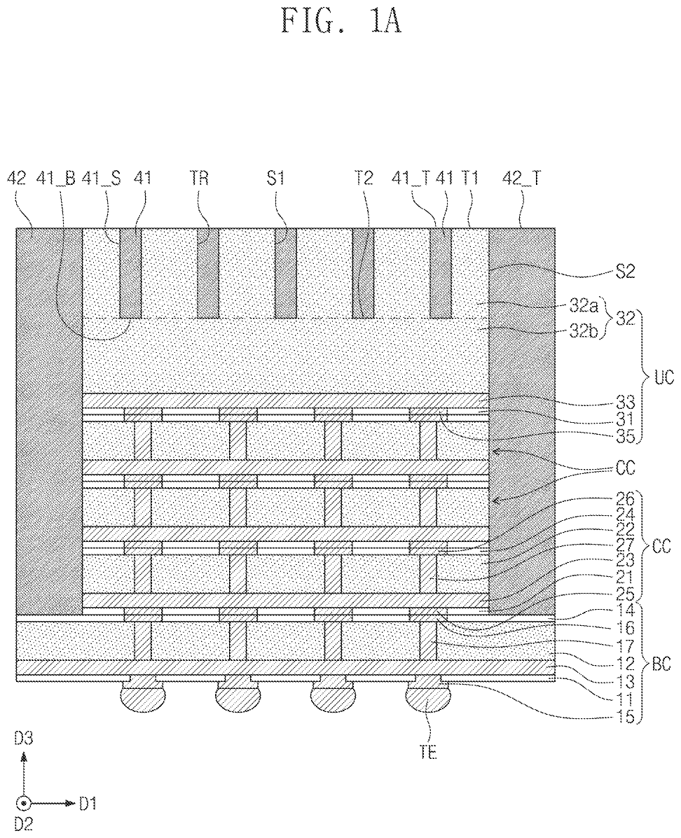

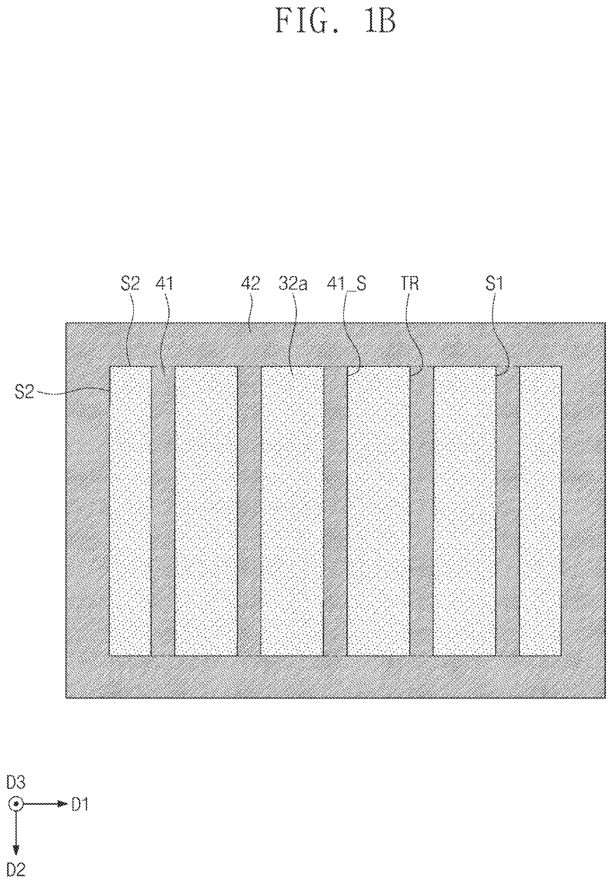

FIG. 1A is a sectional view illustrating a semiconductor package according to an embodiment of the inventive concept. FIG. 1B is a plan view illustrating the semiconductor package of FIG. 1A.

Referring to FIGS. 1A and 1B, a semiconductor package may include a base semiconductor chip BC, connection semiconductor chips CC, an upper semiconductor chip UC, a filling layer 41, a mold layer 42, and terminals TE.

The base semiconductor chip BC may include a first lower protection layer 11, a first interconnection structure 13 on the first lower protection layer 11, a first substrate 12 on the first interconnection structure 13, a first upper protection layer 14 on the first substrate 12, first lower pads 15 in the first lower protection layer 11, first upper pads 16 in the first upper protection layer 14, and first penetration vias 17 penetrating the first substrate 12.

The first substrate 12 may be a plate-shaped (i.e., flat) structure that extends in a first direction D1 and a second direction D2. The first and second directions D1 and D2 may not be parallel to each other. As an example, the first and second directions D1 and D2 may be horizontal directions that are orthogonal to each other. The first substrate 12 may be a semiconductor substrate. As an example, the first substrate 12 may be formed of or include at least one of silicon, germanium, silicon germanium, gallium phosphorus, or gallium arsenic. In an embodiment, the first substrate 12 may be a silicon-on-insulator (SOI) substrate or a germanium-on-insulator (GOI) substrate.

The first lower protection layer 11 may cover a bottom surface of the first interconnection structure 13. The first lower protection layer 11 may be formed of or include an insulating material. As an example, the first lower protection layer 11 may be formed of or include an oxide material. In an embodiment, the first lower protection layer 11 may be a multi-layered structure including a plurality of insulating layers.

The first interconnection structure 13 may cover a bottom surface of the first substrate 12. The first substrate 12 may be provided on a top surface of the first interconnection structure 13.

The first interconnection structure 13 may include a first interconnection insulating layer and first conductive structures. The first interconnection insulating layer may be provided on the first lower protection layer 11. The first interconnection insulating layer may be formed of or include an insulating material. In an embodiment, the first interconnection insulating layer may be a multi-layered structure including a plurality of insulating layers.

The first conductive structures may be provided in the first interconnection insulating layer. The first conductive structures may be enclosed by the first interconnection insulating layer. The first conductive structures may include at least one of a conductive pad, a conductive contact, and a conductive line. The first conductive structures of the first interconnection structure 13 may electrically connect the first penetration via 17 to the first lower pad 15.

The first upper protection layer 14 may cover a top surface of the first substrate 12. The first upper protection layer 14 may include an insulating material. As an example, the first upper protection layer 14 may be formed of or include an oxide material. In an embodiment, the first upper protection layer 14 may be a multi-layered structure including a plurality of insulating layers.

The first lower pads 15 may be enclosed by the first lower protection layer 11. The first lower pads 15 may include a conductive material. As an example, the first lower pads 15 may be formed of or include copper.

The first upper pads 16 may be enclosed by the first upper protection layer 14. The first upper pads 16 may include a conductive material. As an example, the first upper pads 16 may be formed of or include copper.

The first penetration via 17 may be connected to the first upper pad 16 and the first interconnection structure 13. The first penetration via 17 may be provided to penetrate the first substrate 12 in a third direction D3 and may electrically connect the first upper pad 16 to the first interconnection structure 13. The third direction D3 may not be parallel to the first and second directions D1 and D2. As an example, the third direction D3 may be a vertical direction that is orthogonal to the first and second directions D1 and D2. The first penetration via 17 may be formed of or include a conductive material.

The base semiconductor chip BC may be a logic semiconductor chip including a logic semiconductor device. The logic semiconductor device of the base semiconductor chip BC may be provided between the first interconnection structure 13 and the first substrate 12. In an embodiment, the base semiconductor chip BC may be a memory semiconductor chip including a memory semiconductor device.

The terminal TE may be connected to the base semiconductor chip BC. The terminal TE may be in contact with the first lower pad 15. The terminal TE may be formed of or include a conductive material. The semiconductor package may be electrically connected to an external device through the terminal TE.

The connection semiconductor chips CC may be provided on the base semiconductor chip BC. The connection semiconductor chips CC may be stacked on the base semiconductor chip BC in the third direction D3. A width of the connection semiconductor chip CC in the first direction D1 may be smaller than a width of the base semiconductor chip BC in the first direction D1, as illustrated in FIG. 1A.

The number of the connection semiconductor chips CC is not limited to the illustrated example. In an embodiment, four or more connection semiconductor chips CC may be provided.

Each of the connection semiconductor chips CC may include a second lower protection layer 21, a second interconnection structure 23 on the second lower protection layer 21, a second substrate 22 on the second interconnection structure 23, a second upper protection layer 24 on the second substrate 22, second lower pads 25 in the second lower protection layer 21, second upper pads 26 in the second upper protection layer 24, and second penetration vias 27 penetrating the second substrate 22.

The second substrate 22 may be a semiconductor substrate. In an embodiment, the second substrate 22 may be a silicon-on-insulator (SOI) substrate or a germanium-on-insulator (GOI) substrate.

The second lower protection layer 21 may cover a bottom surface of the second interconnection structure 23. The second lower protection layer 21 may include an insulating material. As an example, the second lower protection layer 21 may be formed of or include an oxide material. In an embodiment, the second lower protection layer 21 may be a multi-layered structure including a plurality of insulating layers.

The second interconnection structure 23 may cover a bottom surface of the second substrate 22. The connection semiconductor chip CC may be a memory semiconductor chip including a memory semiconductor device. The memory semiconductor device of the connection semiconductor chip CC may be provided between the second interconnection structure 23 and the second substrate 22.

The second interconnection structure 23 may include a second interconnection insulating layer and second conductive structures. The second interconnection insulating layer may be provided on the second lower protection layer 21. The second interconnection insulating layer may include an insulating material. In an embodiment, the second interconnection insulating layer may be a multi-layered structure including a plurality of insulating layers.

The second conductive structures may be provided in the second interconnection insulating layer. The second conductive structures may be enclosed by the second interconnection insulating layer. The second conductive structures may include at least one of a conductive pad, a conductive contact, and a conductive line. The second conductive structures of the second interconnection structure 23 may electrically connect the second penetration via 27 to the second lower pad 25.

The second upper protection layer 24 may cover a top surface of the second substrate 22. The second upper protection layer 24 may include an insulating material. As an example, the second upper protection layer 24 may be formed of or include an oxide material. In an embodiment, the second upper protection layer 24 may be a multi-layered structure including a plurality of insulating layers.

The second lower pads 25 may be enclosed by the second lower protection layer 21. The second lower pads 25 may be formed of or include a conductive material. As an example, the second lower pads 25 may be formed of or include copper.

The second upper pads 26 may be enclosed by the second upper protection layer 24. The second upper pads 26 may be formed of or include a conductive material. As an example, the second upper pads 26 may be formed of or include copper.

The second penetration via 27 may be connected to the second upper pad 26 and the second interconnection structure 23. The second penetration via 27 may be provided to penetrate the second substrate 22 in the third direction D3 and may electrically connect the second upper pad 26 to the second interconnection structure 23. The second penetration via 27 may be formed of or include a conductive material.

The lowermost one of the connection semiconductor chips CC may be bonded to the base semiconductor chip BC in a hybrid bonding manner. The second lower protection layer 21 of the lowermost one of the connection semiconductor chips CC may be in contact with the first upper protection layer 14 of the base semiconductor chip BC. The second lower pad 25 of the lowermost one of the connection semiconductor chips CC may be in contact with the first upper pad 16 of the base semiconductor chip BC. The connection semiconductor chips CC may be bonded to each other in a hybrid bonding manner.

The upper semiconductor chip UC may be provided on the connection semiconductor chips CC. The upper semiconductor chip UC may be bonded to the uppermost one of the connection semiconductor chips CC in a hybrid bonding manner. A width of the upper semiconductor chip UC in the first direction D1 may be equal to a width of the connection semiconductor chip CC in the first direction D1, as illustrated in FIG. 1A.

A height of the upper semiconductor chip UC in the third direction D3 may be larger than a height of the connection semiconductor chip CC in the third direction D3 and a height of the base semiconductor chip BC in the third direction D3, as illustrated in FIG. 1A. A distance in the third direction D3 between a top surface T1 and a bottom surface of the upper semiconductor chip UC may be larger than a distance in the third direction D3 between top and bottom surfaces of the connection semiconductor chip CC and a distance in the third direction D3 between top and bottom surfaces of the base semiconductor chip BC. In an embodiment, the height of the upper semiconductor chip UC in the third direction D3 may be equal to or larger than 100 μm.

The upper semiconductor chip UC may include a third lower protection layer 31, a third interconnection structure 33 on the third lower protection layer 31, an upper substrate 32 on the third interconnection structure 33, and third lower pads 35 in the third lower protection layer 31.

The upper substrate 32 may be a semiconductor substrate. In an embodiment, the upper substrate 32 may be a silicon-on-insulator (SOI) substrate or a germanium-on-insulator (GOI) substrate. A height of the upper substrate 32 in the third direction D3 may be larger than a height of the first and second substrates 12 and 22 in the third direction D3.

The third lower protection layer 31 may cover a bottom surface of the third interconnection structure 33. The third lower protection layer 31 may include an insulating material. As an example, the third lower protection layer 31 may be formed of or include an oxide material. In an embodiment, the third lower protection layer 31 may be a multi-layered structure including a plurality of insulating layers. The third lower protection layer 31 may be in contact with the second upper protection layer 24 of the uppermost one of the connection semiconductor chips CC.

The third interconnection structure 33 may cover a bottom surface of the upper substrate 32. The upper semiconductor chip UC may be a memory semiconductor chip including a memory semiconductor device. The memory semiconductor device of the upper semiconductor chip UC may be provided between the third interconnection structure 33 and the upper substrate 32. In an embodiment, the upper semiconductor chip UC may be a dummy semiconductor chip, which does not include a semiconductor device.

The third interconnection structure 33 may include a third interconnection insulating layer and third conductive structures. The third interconnection insulating layer may be provided on the third lower protection layer 31. The third interconnection insulating layer may be formed of or include an insulating material. In an embodiment, the third interconnection insulating layer may be a multi-layered structure including a plurality of insulating layers.

The third conductive structures may be provided in the third interconnection insulating layer. The third conductive structures may be enclosed by the third interconnection insulating layer. The third conductive structures may include at least one of a conductive pad, a conductive contact, and a conductive line. The third conductive structures of the third interconnection structure 33 may be electrically connected to the third lower pad 35.

The third lower pads 35 may be enclosed by the third lower protection layer 31. The third lower pad 35 may be in contact with the second upper pad 26 of the uppermost one of the connection semiconductor chips CC. The third lower pads 35 may be formed of or include a conductive material. As an example, the third lower pads 35 may be formed of or include copper.

The upper semiconductor chip UC may be provided to define trenches TR (i.e., the trenches TR are formed within the upper semiconductor chip UC, as illustrated). The trenches TR may have a straight (i.e., non-curved) shape that extend along the second direction D2. The trenches TR may be spaced apart from each other in the first direction D1.

The filling layer 41 may be provided in the trenches TR. The filling layers 41 may have a straight shape that is extended in the second direction D2. The filling layers 41 may be spaced apart from each other in the first direction D1.

The mold layer 42 may be provided to enclose (i.e., extend around) the upper semiconductor chip UC and the connection semiconductor chips CC, as illustrated. The mold layer 42 may enclose (i.e., extend around) the filling layers 41, as illustrated. The mold layer 42 may be provided on the base semiconductor chip BC.

The filling layer 41 and the mold layer 42 may be formed of or include the same material. In an embodiment, the mold layer 42 and the filling layer 41 may be formed of or include a polymer material. As an example, the polymer material may include an epoxy molding compound (EMC). The filling layer 41 and the mold layer 42 may be connected to each other without any observable interface therebetween, thereby forming a monolithic structure.

The trenches TR may be defined by the upper substrate 32. The upper substrate 32 may include upper portions 32a defining side surfaces of the trenches TR and a lower portion 32b defining bottom surfaces of the trenches TR.

The upper portions 32a of the upper substrate 32 may be provided on the lower portion 32b of the upper substrate 32. The upper portions 32a of the upper substrate 32 may have a straight (i.e., non-curved) shape that extends in the second direction D2. The upper portions 32a of the upper substrate 32 may be spaced apart from each other in the first direction D1, as illustrated in FIG. 1A. The filling layers 41 may be provided between the upper portions 32a of the upper substrate 32. The upper portions 32a of the upper substrate 32 may be spaced apart from each other by the filling layers 41. The lower portion 32b of the upper substrate 32 may be in contact with a bottom surface 41_B of the filling layer 41. A height of the upper portion 32a of the upper substrate 32 in the third direction D3 may be equal to a height of the filling layer 41 in the third direction D3.

The top surface T1 of the upper semiconductor chip UC, a top surface 41_T of the filling layer 41, and a top surface 42_T of the mold layer 42 may be coplanar with each other. A level of the top surface T1 of the upper semiconductor chip UC, a level of the top surface 41_T of the filling layer 41, and a level of the top surface 42_T of the mold layer 42 may be the same as each other. The top surface T1 of the upper semiconductor chip UC may be a top surface of the upper portion 32a of the upper substrate 32. A top surface T2 of the lower portion 32b of the upper substrate 32 may be in contact with the bottom surface 41_B of the filling layer 41. The top surface T2 of the lower portion 32b of the upper substrate 32 may be connected to a side surface of the upper portion 32a of the upper substrate 32.

The upper semiconductor chip UC may include inner side surfaces S1 in contact with the filling layer 41 and outer side surfaces S2 in contact with the mold layer 42. A length of the inner side surfaces S1 of the upper semiconductor chip UC in the third direction D3 may be smaller than a length of the outer side surfaces S2 of the upper semiconductor chip UC in the third direction D3, as illustrated in FIG. 1A. The inner side surface S1 of the upper semiconductor chip UC may be a side surface of the upper portion 32a of the upper substrate 32. The outer side surface S2 of the upper semiconductor chip UC may include a side surface of the upper portion 32a of the upper substrate 32 and a side surface of the lower portion 32b of the upper substrate 32. A side surface 41_S of the filling layer 41 may be in contact with the inner side surface S1 of the upper semiconductor chip UC.

The inner side surface S1 of the upper semiconductor chip UC may define a side surface of the trench TR. The top surface T2 of the lower portion 32b of the upper substrate 32 may define a bottom surface of the trench TR.

In a semiconductor package according to an embodiment of the inventive concept, since the trenches TR and the filling layers 41 are provided in the upper semiconductor chip UC, the rigidity of the upper semiconductor chip UC may be relatively lowered. Thus, it may be possible to prevent or suppress a void from being formed between the upper semiconductor chip UC the connection semiconductor chip CC.

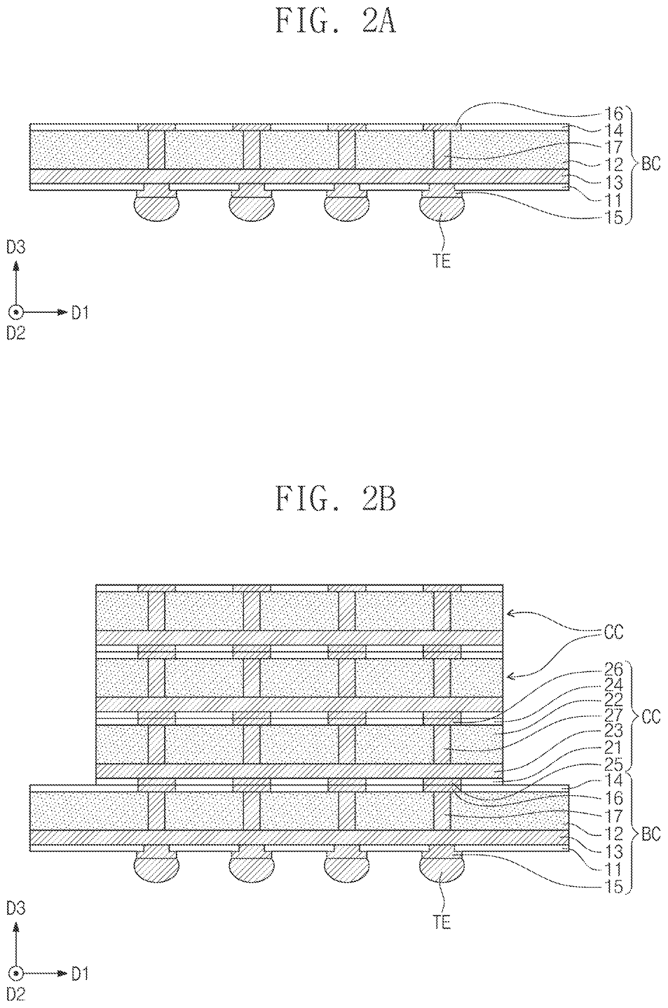

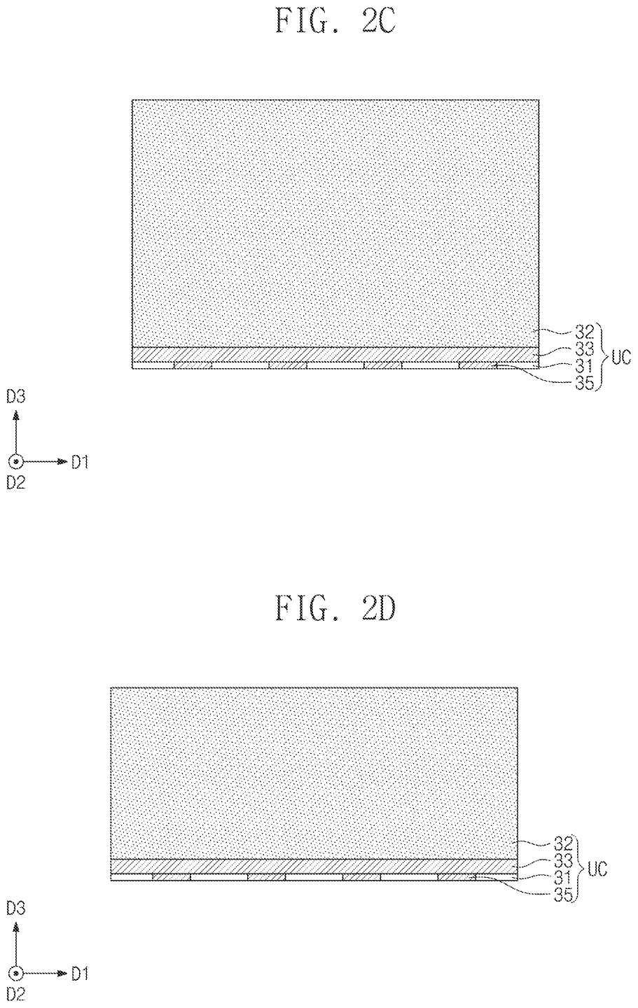

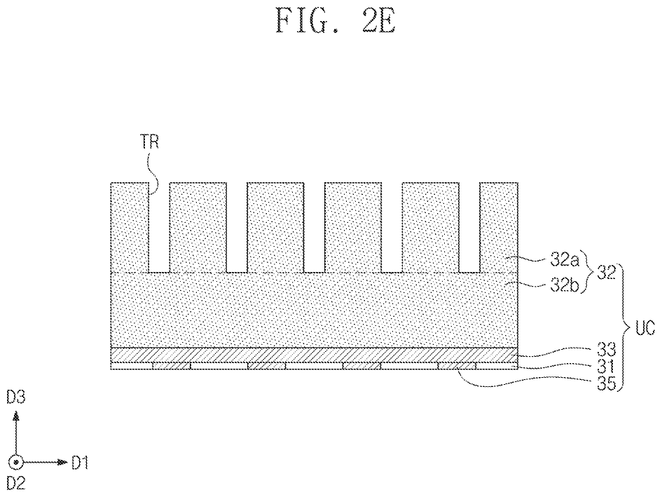

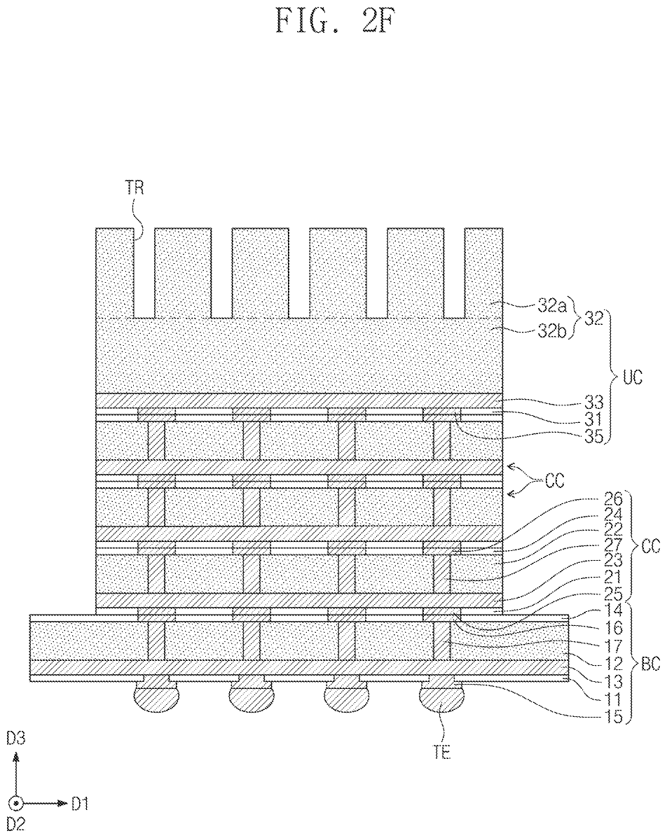

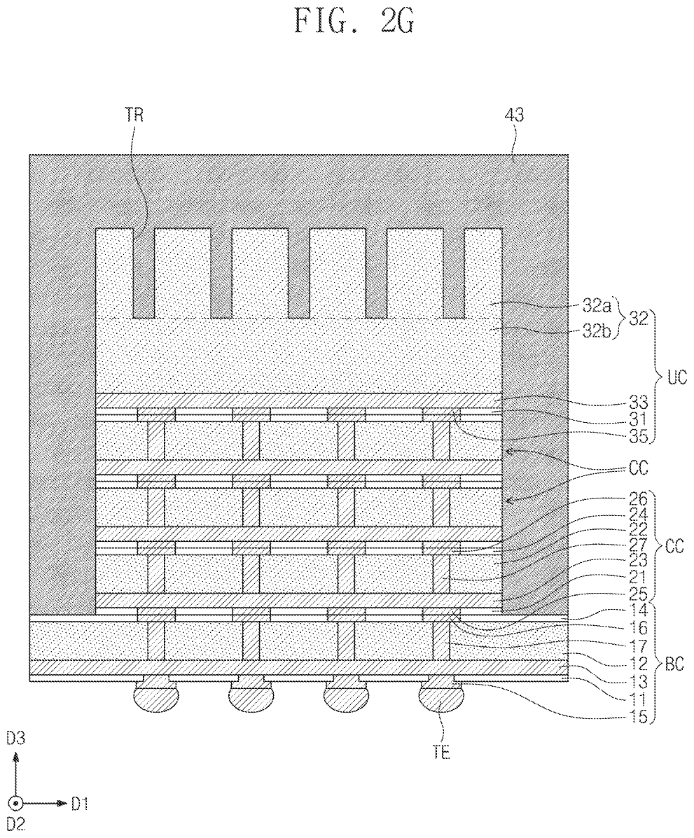

FIGS. 2A, 2B, 2C, 2D, 2E, 2F, and 2G are sectional views illustrating a method of fabricating the semiconductor package of FIGS. 1A and 1B.

Referring to FIG. 2A, the base semiconductor chip BC may be formed. The terminal TE may be formed to be connected to the first lower pad 15 of the base semiconductor chip BC.

Referring to FIG. 2B, the connection semiconductor chips CC may be formed on the base semiconductor chip BC. The lowermost one of the connection semiconductor chips CC may be bonded to the base semiconductor chip BC through a hybrid bonding process. The connection semiconductor chips CC may be bonded to each other through a hybrid bonding process.

Referring to FIG. 2C, the upper semiconductor chip UC may be formed. The formation of the upper semiconductor chip UC may include forming the third interconnection structure 33 on the upper substrate 32 and forming the third lower pads 35 and the third lower protection layer 31 on the third interconnection structure 33. After the formation of the third lower pads 35 and the third lower protection layer 31, the upper substrate 32 may be flipped.

Referring to FIG. 2D, a process of thinning the upper substrate 32 may be performed to reduce a height of the upper substrate 32 in the third direction D3.

Referring to FIG. 2E, the trenches TR may be formed in the upper semiconductor chip UC. The trenches TR may be formed in the upper substrate 32 of the upper semiconductor chip UC. As a result of the formation of the trenches TR, the lower portion 32b and the upper portions 32a of the upper substrate 32 may be defined.

Referring to FIG. 2F, the upper semiconductor chip UC may be provided on (i.e., bonded to) the connection semiconductor chips CC. For example, the upper semiconductor chip UC may be bonded to the connection semiconductor chip CC through a hybrid bonding process.

Referring to FIG. 2G, a preliminary mold layer 43 may be formed to cover the connection semiconductor chips CC and the upper semiconductor chip UC. The preliminary mold layer 43 may fill the trenches TR. The preliminary mold layer 43 may cover a top surface of the upper semiconductor chip UC. The preliminary mold layer 43 may be formed on the base semiconductor chip BC. The preliminary mold layer 43 may be formed of or include a polymer material.

Referring to FIGS. 1A and 1B, a process of thinning the preliminary mold layer 43 may be performed to remove an upper portion of the preliminary mold layer 43. As a result of the removal of the upper portion of the preliminary mold layer 43, the top surface T1 of the upper semiconductor chip UC may be exposed. The upper portion of the preliminary mold layer 43 may be removed to form the filling layers 41 and the mold layer 42.

In a method of fabricating a semiconductor package according to an embodiment of the inventive concept, the trenches TR may be formed in the upper semiconductor chip UC to reduce the rigidity of the upper semiconductor chip UC, and this may allow for bonding the upper semiconductor chip UC to the connection semiconductor chip CC in a hybrid bonding manner. That is, the upper semiconductor chip UC may be more easily deformed in a process of bonding the upper semiconductor chip UC to the connection semiconductor chip CC. Furthermore, the bonding process may start from center portions of the upper and connection semiconductor chips UC and CC and progress towards edge portions of the upper and connection semiconductor chips UC and CC, and thus, it may be possible to prevent or suppress voids from being formed between the center portions of the upper and connection semiconductor chips UC and CC.

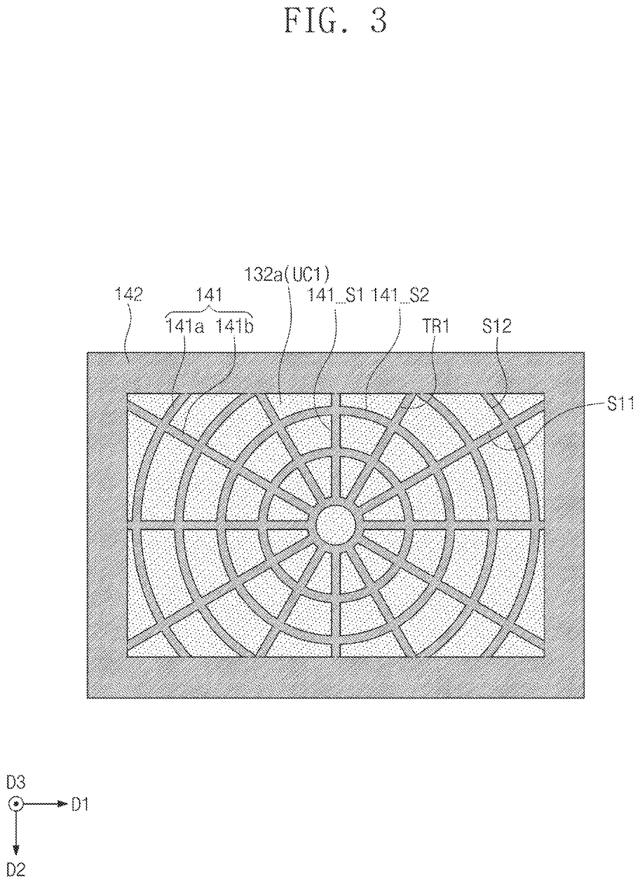

FIG. 3 is a plan view illustrating a semiconductor package according to an embodiment of the inventive concept.

Referring to FIG. 3, a semiconductor package may include an upper semiconductor chip UC1, a filling layer 141, and a mold layer 142. The upper semiconductor chip UC1, the filling layer 141, and the mold layer 142 of FIG. 3 may correspond to the upper semiconductor chip UC, the filling layer 41, and the mold layer 42 of FIGS. 1A and 1B.

A trench TR1 may be defined by the upper semiconductor chip UC1. The filling layer 141 may be provided to fill the trench TR1. The filling layer 141 may include straight portions 141b and curved portions 141a, as illustrated. The straight portions 141b of the filling layer 141 may have a straight (i.e., non-curved) shape, when viewed in the plan view of FIG. 3. The curved portions 141a of the filling layer 141 may have a curved shape, when viewed in the plan view of FIG. 3.

An upper portion 132a of an upper substrate of the upper semiconductor chip UC1 may include a first flat side surface S11 and a first curved side surface S12. The first flat side surface S11 may be in contact with the straight portion 141b. The first curved side surface S12 may be in contact with the curved portion 141a. The first flat side surface S11 may be flat (i.e., non-curved). The first curved side surface S12 may be curved.

The filling layer 141 may include a second flat side surface 141_S1 and a second curved side surface 141_S2. The second flat side surface 141_S1 may be in contact with the first flat side surface S11. The second curved side surface 141_S2 may be in contact with the first curved side surface S12. The second flat side surface 141_S1 may be flat (i.e., non-curved). The second curved side surface 141_S2 may be curved. The second flat side surface 141_S1 may be a side surface of the straight portion 141b. The second curved side surface 141_S2 may be a side surface of the curved portion 141a.

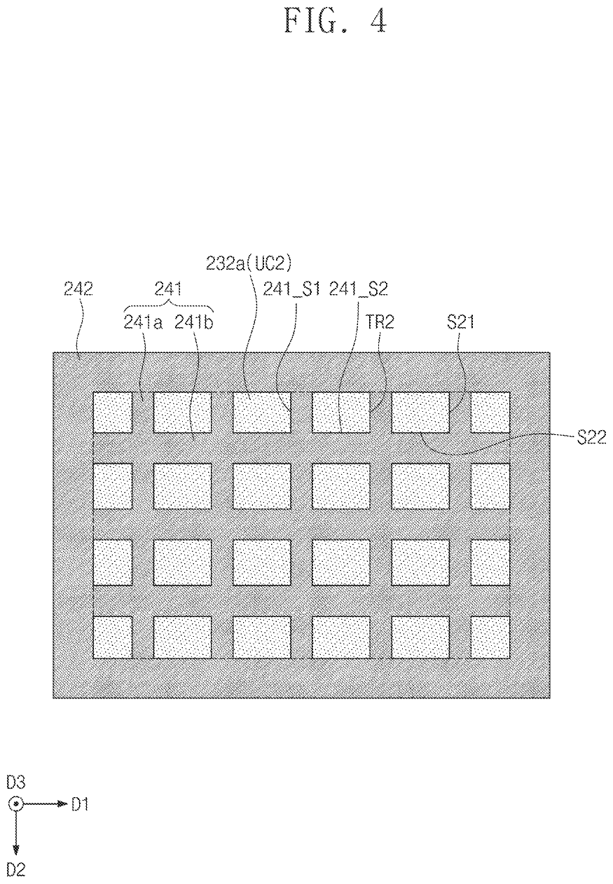

FIG. 4 is a plan view illustrating a semiconductor package according to an embodiment of the inventive concept.

Referring to FIG. 4, a semiconductor package may include an upper semiconductor chip UC2, a filling layer 241, and a mold layer 242. The upper semiconductor chip UC2, the filling layer 241, and the mold layer 242 of FIG. 4 may correspond to the upper semiconductor chip UC, the filling layer 41, and the mold layer 42 of FIGS. 1A and 1B.

A trench TR2 may be defined by the upper semiconductor chip UC2. The filling layer 241 may be provided to fill the trench TR2. The filling layer 241 may include first straight portions 241a and second straight portions 241b. The first straight portion 241a may have a straight (i.e., non-curved) shape that extends in the second direction D2. The second straight portion 241b may have a straight shape that is extended in the first direction D1.

An upper portion 232a of an upper substrate of the upper semiconductor chip UC2 may include a first side surface S21 in contact with the first straight portion 241a and a second side surface S22 in contact with the second straight portion 241b. The first side surface S21 may be parallel to the second direction D2. The second side surface S22 may be parallel to the first direction D1.

The filling layer 241 may include a third side surface 241_S1 in contact with the first side surface S21 and a fourth side surface 241_S2 in contact with the second side surface S22.

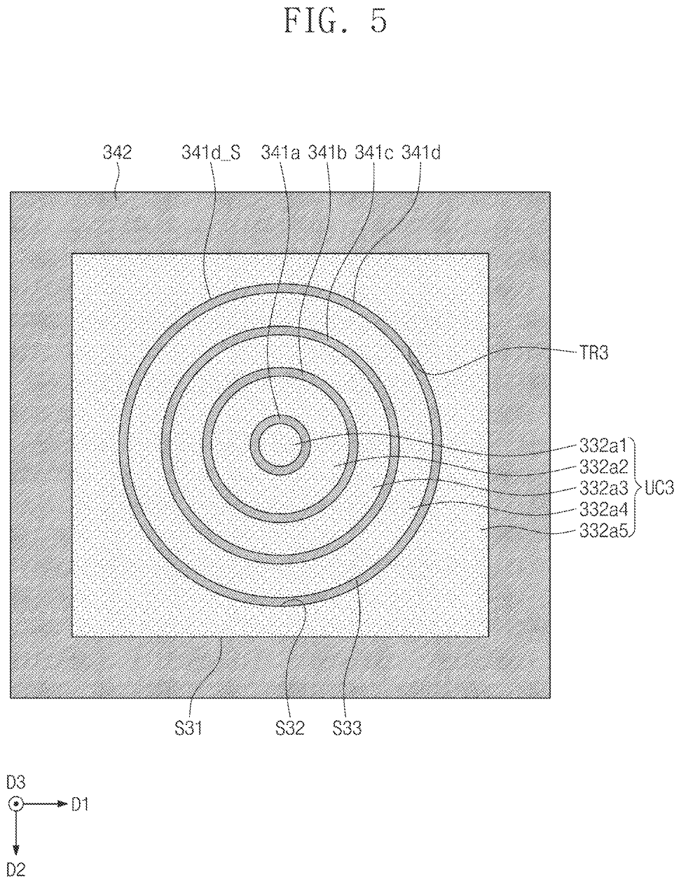

FIG. 5 is a plan view illustrating a semiconductor package according to an embodiment of the inventive concept.

Referring to FIG. 5, a semiconductor package may include an upper semiconductor chip UC3, first to fourth filling layers 341a, 341b, 341c, and 341d, and a mold layer 342. The upper semiconductor chip UC3, the first to fourth filling layers 341a, 341b, 341c, and 341d, and the mold layer 342 of FIG. 5 may correspond to the upper semiconductor chip UC, the filling layer 41, and the mold layer 42 of FIGS. 1A and 1B.

Trenches TR3 may be defined by the upper semiconductor chip UC3. The trenches TR3 may be enclosed by the upper semiconductor chip UC3. The trenches TR3 may be spaced apart from the mold layer 342.

The first to fourth filling layers 341a, 341b, 341c, and 341d may be provided to fill the trenches TR3, respectively. Each of the first to fourth filling layers 341a, 341b, 341c, and 341d may have a circular shape, when viewed in the plan view of FIG. 5. The first to fourth filling layers 341a, 341b, 341c, and 341d may be radially spaced apart from each other (e.g., concentrically spaced apart). The first to fourth filling layers 341a, 341b, 341c, and 341d may be spaced apart from the mold layer 342. The second filling layer 341b may be provided to enclose (i.e., concentrically surround) the first filling layer 341a. The third filling layer 341c may be provided to enclose (i.e., concentrically surround) the second filling layer 341b. The fourth filling layer 341d may be provided to enclose (i.e., concentrically surround) the third filling layer 341c.

Upper portions 332a1, 332a2, 332a3, 332a4, and 332a5 of an upper substrate of the upper semiconductor chip UC3 may include the outermost portion 332a5, which is in contact with the mold layer 342, and the first to fourth inner portions 332a1, 332a2, 332a3, and 332a4, which are enclosed by the outermost portion 332a5. The second inner portion 332a2 may be provided to enclose (i.e., concentrically surround) the first inner portion 332a1, the third inner portion 332a3 may be provided to enclose (i.e., concentrically surround) the second inner portion 332a2, and the fourth inner portion 332a4 may be provided to enclose (i.e., concentrically surround) the third inner portion 332a3. The first to fourth inner portions 332a1, 332a2, 332a3, and 332a4 may be enclosed (i.e., concentrically surrounded) by the fourth filling layer 341d.

An outer side surface S31 of the outermost portion 332a5 may be flat. The outer side surface S31 of the outermost portion 332a5 may be in contact with the mold layer 342. An inner side surface S32 of the outermost portion 332a5 may be curved. The inner side surface S32 of the outermost portion 332a5 may be curved. An outer side surface S33 of the fourth inner portion 332a4 may be curved. An outer side surface 341d S of the fourth filling layer 341d may be in contact with the inner side surface S32 of the outermost portion 332a5. The outer side surface 341d_S of the fourth filling layer 341d may be curved.

The first to fourth filling layers 341a, 341b, 341c, and 341d may be formed of or include the same material as the mold layer 342. In an embodiment, the first to fourth filling layers 341a, 341b, 341c, and 341d may be formed of or include a material different from the mold layer 342. In this case, the first to fourth filling layers 341a, 341b, 341c, and 341d may be formed of or include a heat-dissipation material (e.g., a thermal interface material (TIM)), and the mold layer 342 may be formed of or include a polymer material (e.g., an EMC).

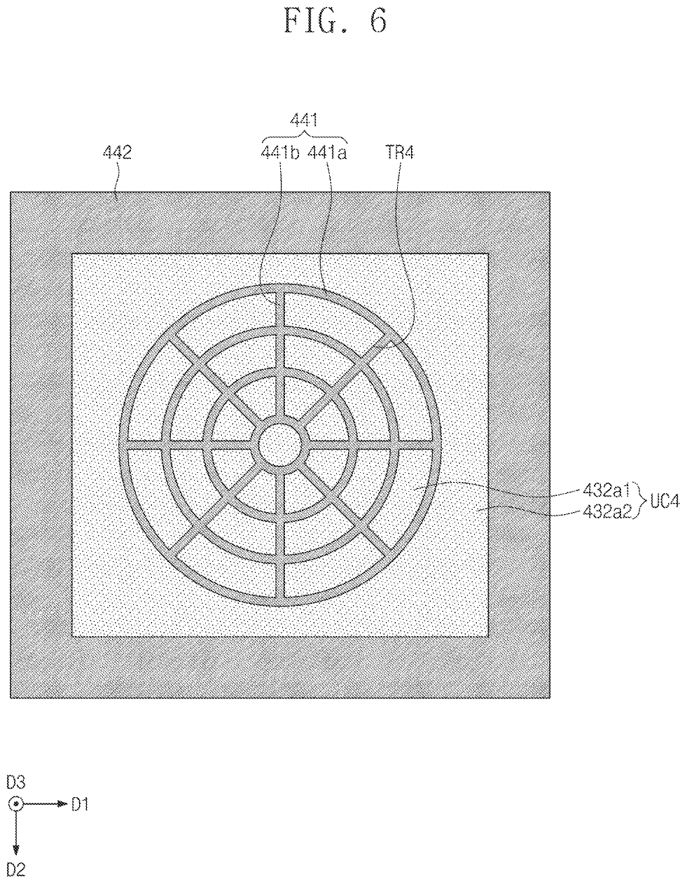

FIG. 6 is a plan view illustrating a semiconductor package according to an embodiment of the inventive concept.

Referring to FIG. 6, a semiconductor package may include an upper semiconductor chip UC4, a filling layer 441, and a mold layer 442. The upper semiconductor chip UC4, the filling layer 441, and the mold layer 442 of FIG. 6 may correspond to the upper semiconductor chip UC, the filling layer 41, and the mold layer 42 of FIGS. 1A and 1B.

A trench TR4 may be defined by the upper semiconductor chip UC4. The filling layer 441 may be provided to fill the trench TR4. The filling layer 441 may include straight portions 441b and curved portions 441a. The straight portions 441b of the filling layer 441 may have a straight shape, when viewed in the plan view of FIG. 6. The curved portions 441a of the filling layer 441 may have a curved shape, when viewed in the plan view of FIG. 6.

Upper portions 432a1 and 432a2 of an upper substrate of the upper semiconductor chip UC4 may include the outermost portion 432a2 and the inner portions 432a1. The outermost portion 432a2 may be in contact with the mold layer 442 and the filling layer 441. The inner portions 432a1 may be enclosed (i.e., surrounded) by the filling layer 441. The filling layer 441 may be spaced apart from the mold layer 442 by the outermost portion 432a2.

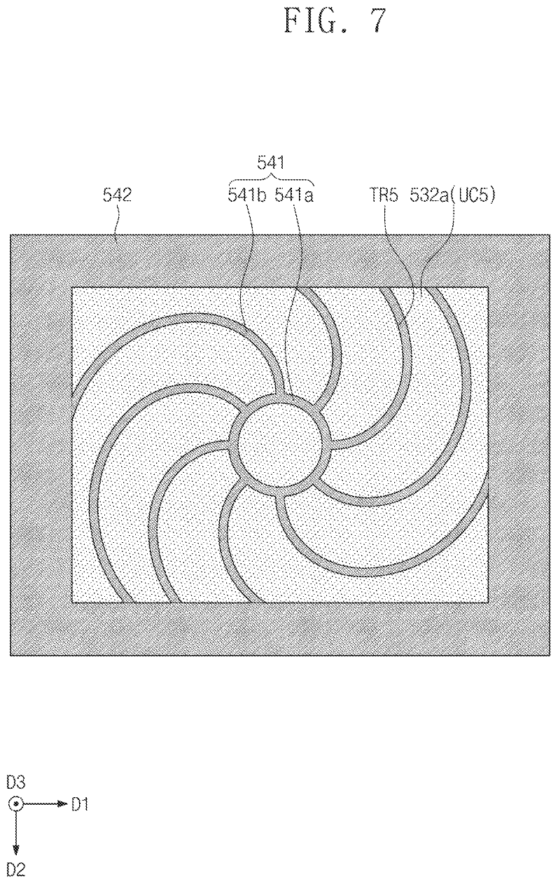

FIG. 7 is a plan view illustrating a semiconductor package according to an embodiment of the inventive concept.

Referring to FIG. 7, a semiconductor package may include an upper semiconductor chip UC5, a filling layer 541, and a mold layer 542. The upper semiconductor chip UC5, the filling layer 541, and the mold layer 542 of FIG. 7 may correspond to the upper semiconductor chip UC, the filling layer 41, and the mold layer 42 of FIGS. 1A and 1B.

A trench TR5 may be defined by the upper semiconductor chip UC5. The filling layer 541 may fill the trench TR5. The filling layer 541 may include a circular portion 541a and curved portions 541b. The circular portion 541a of the filling layer 541 may have a circular shape, when viewed in the plan view of FIG. 7. The curved portion 541b of the filling layer 541 may have a curved shape, when viewed in the plan view of FIG. 7. The curved portions 541b may be connected to the circular portion 541a and the mold layer 542. Upper portions 532a of an upper substrate of the upper semiconductor chip UC5 may be spaced apart from each other by the filling layer 541.

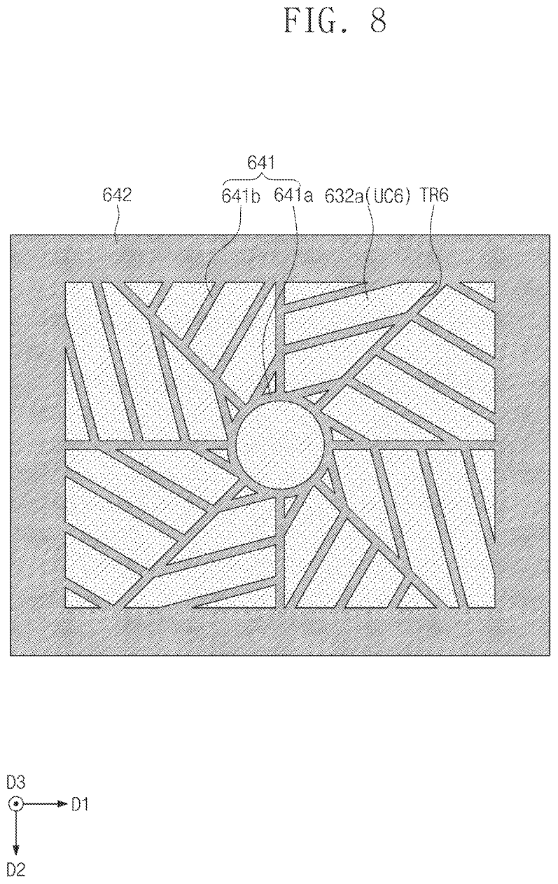

FIG. 8 is a plan view illustrating a semiconductor package according to an embodiment of the inventive concept.

Referring to FIG. 8, a semiconductor package may include an upper semiconductor chip UC6, a filling layer 641, and a mold layer 642. The upper semiconductor chip UC6, the filling layer 641, and the mold layer 642 of FIG. 8 may correspond to the upper semiconductor chip UC, the filling layer 41, and the mold layer 42 of FIGS. 1A and 1B.

A trench TR6 may be defined by the upper semiconductor chip UC6. The filling layer 641 may fill the trench TR6. The filling layer 641 may include a circular portion 641a and straight portions 641b. The circular portion 641a may have a circular shape, when viewed in the plan view of FIG. 8. The straight portion 641b may have a straight shape, when viewed in the plan view of FIG. 8. Upper portions 632a of an upper substrate of the upper semiconductor chip UC6 may be spaced apart from each other by the filling layer 641.

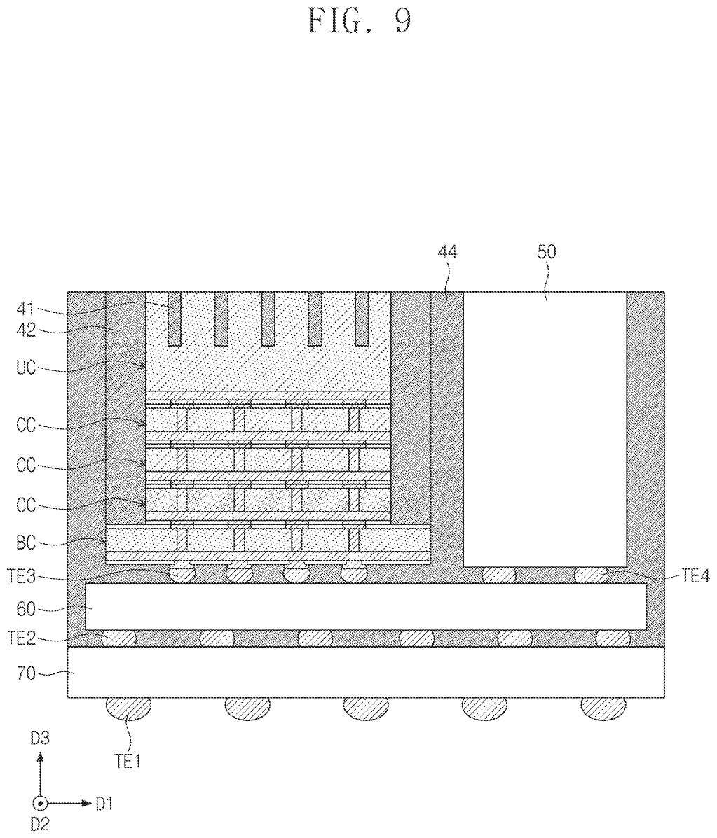

FIG. 9 is a sectional view illustrating a semiconductor package according to an embodiment of the inventive concept.

Referring to FIG. 9, a semiconductor package may include first terminals TE1, a package substrate 70, second terminals TE2, an interposer 60, third terminals TE3, the base semiconductor chip BC, the connection semiconductor chips CC, the upper semiconductor chip UC, the filling layers 41, the mold layer 42, fourth terminals TE4, a processor chip 50, and a package mold layer 44.

The upper semiconductor chip UC, the connection semiconductor chip CC, the base semiconductor chip BC, the filling layer 41, the mold layer 42, and the third terminal TE3 of FIG. 9 may correspond to the upper semiconductor chip UC, the connection semiconductor chip CC, the base semiconductor chip BC, the filling layer 41, the mold layer 42, and the terminal TE of FIGS. 1A and 1B.

The package substrate 70 may be provided on the first terminals TE1. For example, the package substrate 70 may be a printed circuit board. The semiconductor package may be mounted on an external device (e.g., a main board) through the first terminals TE1. The first terminals TE1 may be formed of or include a conductive material.

The interposer 60 may be provided on the package substrate 70. The second terminals TE2 may be provided to electrically connect the package substrate 70 to the interposer 60. The second terminals TE2 may be formed of or include a conductive material.

The processor chip 50 may be provided on the interposer 60. The processor chip 50 may be, for example, a graphics processing unit (GPU) or a central processing unit (CPU). The fourth terminals TE4 may be provided to electrically connect the processor chip 50 to the interposer 60. The fourth terminals TE4 may be formed of or include a conductive material.

The base semiconductor chip BC, the connection semiconductor chips CC, and the upper semiconductor chip UC may be provided on the interposer 60. The filling layers 41 may be provided in the upper semiconductor chip UC. The mold layer 42 may be provided to enclose (i.e., extend around) the upper semiconductor chip UC and the connection semiconductor chips CC, as illustrated. The base semiconductor chip BC and the interposer 60 may be electrically connected to each other through the third terminals TE3.

The package mold layer 44 may be provided on the package substrate 70. The package mold layer 44 may be provided to enclose the interposer 60, the processor chip 50, the base semiconductor chip BC, and the mold layer 42. The package mold layer 44 may be formed of or include a polymer material.

In a semiconductor package according to an embodiment of the inventive concept, a trench and a filling layer may be provided in an upper semiconductor chip. In this case, the upper semiconductor chip may have a relatively low rigidity, and it may be possible to prevent the formation of a void between the upper semiconductor chip and a connection semiconductor chip.

While example embodiments of the inventive concept have been particularly shown and described, it will be understood by one of ordinary skill in the art that variations in form and detail may be made therein without departing from the scope of the attached claims.

1. A semiconductor package, comprising:
a base semiconductor chip;
a connection semiconductor chip on the base semiconductor chip;
an upper semiconductor chip on the connection semiconductor chip, the upper semiconductor chip comprising a trench;
a filling layer in the trench; and
a mold layer extending around the upper semiconductor chip.

2. The semiconductor package of claim 1, wherein the trench is in an upper portion of the upper semiconductor chip.

3. The semiconductor package of claim 1, wherein the upper semiconductor chip comprises:
a lower pad on the connection semiconductor chip;
an interconnection structure electrically connected to the lower pad; and
an upper substrate on the interconnection structure,
wherein the trench is in the upper substrate.

4. The semiconductor package of claim 3, wherein the upper substrate comprises an upper portion and a lower portion, wherein a side surface of the trench is in the upper portion, and a bottom surface of the trench is a top surface of the bottom portion.

5. The semiconductor package of claim 4, wherein the upper portion of the upper substrate comprises a flat side surface and a curved side surface.

6. The semiconductor package of claim 1, wherein the filling layer and the mold layer are connected to each other without any interface therebetween, thereby forming a monolithic structure.

7. The semiconductor package of claim 1, wherein the filling layer comprises a flat side surface and a curved side surface.

8. The semiconductor package of claim 1, wherein the filling layer is spaced apart from the mold layer.

9. The semiconductor package of claim 1, wherein a top surface of the filling layer, a top surface of the upper semiconductor chip, and a top surface of the mold layer are coplanar.

10. A semiconductor package, comprising:
a base semiconductor chip;
a connection semiconductor chip on the base semiconductor chip;
an upper semiconductor chip on the connection semiconductor chip;
a filling layer in the upper semiconductor chip; and
a mold layer extending around the upper semiconductor chip,
wherein the upper semiconductor chip comprises an inner side surface in contact with the filling layer and an outer side surface in contact with the mold layer.

11. The semiconductor package of claim 10, wherein the filling layer is surrounded by the mold layer.

12. The semiconductor package of claim 10, wherein the upper semiconductor chip comprises a lower portion, which is in contact with a bottom surface of the filling layer, and upper portions, which are on the lower portion of the upper semiconductor chip,
wherein the upper portions of the upper semiconductor chip are spaced apart from each other by the filling layer.

13. The semiconductor package of claim 12, wherein the upper portions of the upper semiconductor chip comprises an outermost portion, which is in contact with the mold layer, and inner portions, which are surrounded by the outermost portion,
wherein an outer side surface of the outermost portion is flat, and
wherein an inner side surface of the outermost portion is curved.

14. The semiconductor package of claim 10, wherein the filling layer comprises a plurality of first straight portions, which extend in a first direction, and a plurality of second straight portions, which extend in a second direction transverse to the first direction.

15. The semiconductor package of claim 10, wherein the inner side surface of the upper semiconductor chip is curved, and
wherein the outer side surface of the upper semiconductor chip is flat.

16. The semiconductor package of claim 10, wherein the mold layer and the filling layer comprise the same material.

17. The semiconductor package of claim 10, wherein the mold layer and the filling layer comprise respective different materials.

18. The semiconductor package of claim 10, wherein a height of the upper semiconductor chip is larger than a height of the connection semiconductor chip.

19. A semiconductor package, comprising:
a base semiconductor chip;
terminals connected to the base semiconductor chip;
a connection semiconductor chip on the base semiconductor chip;
an upper semiconductor chip on the connection semiconductor chip;
a filling layer in the upper semiconductor chip; and
a mold layer extending around the connection semiconductor chip and the upper semiconductor chip,
wherein the upper semiconductor chip comprises:
a lower pad in contact with the connection semiconductor chip;
an interconnection structure electrically connected to the lower pad; and
an upper substrate on the interconnection structure,
wherein the upper substrate comprises a lower portion and a plurality of upper portions, and
wherein the plurality of upper portions of the upper substrate are spaced apart from each other by the filling layer.

20. The semiconductor package of claim 19, wherein a top surface of the lower portion of the upper substrate is in contact with a bottom surface of the filling layer, and
wherein a side surface of each of the plurality of upper portions of the upper substrate is in contact with a side surface of the filling layer.

21.-28. (canceled)
